(19) United States
(12) Patent Application Publication
(10) Pub. No.: US 2016/0141338 A1
(43) Pub. Date: May 19, 2016

(54) TANDEM-TYPE ORGANIC LIGHT-EMITTING DIODE AND DISPLAY DEVICE

(71) Applicant: Shenzhen China Star Optotlectronics Technology Co. Ltd., Shenzhen, Guangdong (CN)

(72) Inventor: Xianjie Li, Shenzhen (CN)

(73) Assignee: Shenzhen China Star Optoelectronics Technology Co. Ltd., Shenzhen, Guangdong (CN)

(21) Appl. No.: 14/408,692

(22) PCT Filed: Nov. 21, 2014
(86) PCT No.: PCT/CN2014/091898

§ 371 Date: Dec. 17, 2014

(30) Foreign Application Priority Data
Nov. 14, 2014 (CN) 2014106634104

(51) Int. Cl. H01L 27/32; H01L 51/50

(52) U.S. Cl. CPC H01L 27/3209; H01L 51/5088; H01L 51/5092; H01L 51/504; H01L 2251/558; H01L 2251/301; H01L 2251/303; H01L 51/0072

(57) ABSTRACT

A tandem-type organic light-emitting diode (OLED) and a display device are provided. The tandem-type OLED includes a substrate, a first electrode, a first light-emitting unit, a charge generate layer, a second light-emitting unit and a second electrode. The first electrode is disposed on the substrate, the first light-emitting unit is disposed on the first electrode, the charge generate layer is disposed on the first light-emitting unit is disposed on the first light-emitting unit, the second light-emitting unit is disposed on the charge generate layer, and the second electrode is disposed on the second light-emitting unit. The charge generate layer includes stacked first electron transport layer and active metal layer. Accordingly, the tandem-type OLED with stable performance is obtained and in favor of mass production.

### TECHNICAL FIELD

The present invention relates to the field of display technology, and particularly to a tandem-type organic light-emitting diode and a display device.

### DESCRIPTION OF RELATED ART

An organic light-emitting diode (OLED) has the advantages of self-emissive, high color saturation and high contrast, etc., and is the core of next generation of flat panel display technology and flexible display technology. Currently, small-sized OLED display screens have been used in mobile phones and tablet PCs, and a cost thereof has been close to that of the liquid crystal display screen. However, large-sized OLED display screens still have the outstanding issues of high cost and short lifespan, etc., which would affect the competition with respect to the large-sized liquid crystal display screens.

Currently, a technology applied to the large-sized OLED display screens generally is white OLED (also referred to as WOLED) plus color filter, and such technology has the potential of greatly improving the product yield. The WOLED generally adopts a tandem-type WOLED.

The tandem-type WOLED can exponentially increase efficiency and lifespan of device and thus is a core technology of the large-sized OLED display screens. A charge generate layer (CGL) is a key part of the tandem-type WOLED. A current most commonly used CGL structure is n-ETL (n-type electron transport layer)/metal oxide or HATCN (hexanitrilehexaazatriphenylene)/p-HTL (p-type hole transport layer). The n-ETL layer usually is formed by using an active metal to dope an ETL layer, the doping proportion has a great impact on device performance and thus high doping accuracy is required, which goes against the mass production.

### SUMMARY

A technical problem mainly to be solved by the invention is to provide a tandem-type organic light-emitting diode and a display device, capable of manufacturing a tandem-type organic light-emitting diode with stable performance and being in favor of mass production.

In order to solve the above technical problem, a technical solution adopted by the invention is to provide a tandem-type organic light-emitting diode. The organic light-emitting diode includes: a substrate, a first electrode disposed on the substrate, a first light-emitting unit disposed on the first electrode, a charge generate layer disposed on the first light-emitting unit, a second light-emitting unit disposed on the charge generate layer, a second electrode, disposed on the second light-emitting unit. The charge generate layer includes a first electron transport layer and an active metal layer stacked with each other.

In an exemplary embodiment, the charge generate layer further includes an electron-hole generate layer and a first hole transport layer sequentially stacked on the first electron transport layer and the active metal layer.

In an exemplary embodiment the active metal layer has a thickness in the range of 0.5 nm-5 nm.

In an exemplary embodiment, the active metal layer is made of an active metal with a work function less than 3 eV.

In an exemplary embodiment, the active metal layer is made of one of lithium (Li), sodium (Na), potassium (K), ruthenium (Ru), cesium (Cs), calcium (Ca), strontium (Sr), barium (Ba), cerium (Ce), praseodymium (Pr), samarium (Sm), europium (Eu), terbium (Tb) and ytterbium (Yb), or a combination thereof

In an exemplary embodiment, the electron-hole generate layer includes a hexanitrilehexaazatriphenylene (HATCN) layer or a metal oxide layer; the metal oxide layer is made of one of molybdenum oxide (MoO3), tungsten trioxide (WO3), vanadium pentoxide (V2O5) and rhenium oxide (ReO3), or a combination thereof.

In an exemplary embodiment, the first light-emitting unit includes a second hole transport layer, a first light-emitting layer and a second electron transport layer sequentially stacked in that order; the second light-emitting unit includes a third hole transport layer, a second light-emitting layer and a third electron transport layer sequentially stacked in that order.

In an exemplary embodiment, one of the first light-emitting unit and the second light-emitting unit is a blue light-emitting element, and the other one of the first light-emitting unit and the second light-emitting unit is a yellow light-emitting element; or the first light-emitting unit and the second light-emitting unit both are white light-emitting elements.

In order to solve the above technical problem, another technical solution adopted by the invention is to provide a tandem-type organic light-emitting diode including a charge generate layer. The charge generate layer includes stacked first electron transport layer and active metal layer.

In order to solve the above technical problem, still another technical solution adopted by the invention is to provide a display device including pixel units arranged in an array. Each of the pixel units is a tandem-type organic light-emitting diode. In particular, the tandem-type organic light-emitting diode includes: a substrate, a first electrode disposed on the substrate, a first light-emitting unit disposed on the first electrode, a charge generate layer disposed on the first light-emitting unit, a second light-emitting unit disposed on the charge generate layer, a second electrode disposed on the second light-emitting unit. The charge generate layer includes stacked first electron transport layer and active metal layer.

In an exemplary embodiment, the charge generate layer further includes an electron-hole generate layer and a first hole transport layer sequentially stacked on the first electron transport layer and the active metal layer.

In an exemplary embodiment, the active metal layer has a thickness in the range of 0.5 nm-5 nm.

In an exemplary embodiment, the active metal layer is made of an active metal with a work function less than 3 eV.

In an exemplary embodiment, the active metal layer is made of one of lithium (Li), sodium (Na), potassium (K), ruthenium (Ru), cesium (Cs), calcium (Ca), strontium (Sr), barium (Ba), cerium (Ce), praseodymium (Pr), samarium (Sm), europium (Eu), terbium (Tb) and ytterbium (Yb), or a combination thereof

In an exemplary embodiment, the electron-hole generate layer includes a hexanitrilehexaazatriphenylene (HATCN) layer or a metal oxide layer; the metal oxide layer is made of one of molybdenum oxide (MoO3), tungsten trioxide (WO3), vanadium pentoxide (V2O5) and rhenium oxide (ReO3), or a combination thereof.

In an exemplary embodiment, the first light-emitting unit includes a second hole transport layer, a first light-emitting layer and a second electron transport layer sequentially stacked in that order; the second light-emitting unit includes a third hole transport layer, a second light-emitting layer and a third electron transport layer sequentially stacked in that order.

In an exemplary embodiment, one of the first light-emitting unit and the second light-emitting unit is a blue light-emitting element, and the other one of the first light-emitting unit and the second light-emitting unit is a yellow light-emitting element; or the first light-emitting unit and the second light-emitting unit both are white light-emitting elements.

The efficacy of the invention is that: different from the prior art, the tandem-type organic light-emitting diode of the invention disposes a charge generate layer including a first electron transport layer and an active metal layer, the first electron transport layer and the active metal layer may be formed independently, the manufacturing processes as well as working processes thereof are not mutually influenced, and therefore the tandem-type organic light-emitting diode with stable performance is obtained and in favor of mass production.

### BRIEF DESCRIPTION OF THE DRAWINGS

In order to more clearly illustrate the technical solutions of various embodiments of the present invention, drawings will be used in the description of embodiments will be given a brief description below. Apparently, the drawings in the following description only are some embodiments of the invention, the ordinary skill in the art can obtain other drawings according to these illustrated drawings without creative effort. In the drawings:

FIG. 1 is a schematic structural view of a tandem-type organic light-emitting diode provided by an embodiment of the invention;

FIG. 2 is a voltage-current density diagram of the tandem-type organic light-emitting diode as shown in FIG. 1 and a tandem-type organic light-emitting diode in the prior art;

FIG. 3 is a voltage-brightness diagram of the tandem-type organic light-emitting diode as shown in FIG. 1 and a tandem-type organic light-emitting diode in the prior art;

FIG. 4 is a schematic structural view of another tandem-type organic light-emitting diode provided by an embodiment of the invention; and

FIG. 5 is a schematic structural view of a display device provided by an embodiment of the invention.

### DETAILED DESCRIPTION OF EMBODIMENTS

In the following, with reference to accompanying drawings of embodiments of the invention, technical solutions in the embodiments of the invention will be clearly and completely described. Apparently, the embodiments of the invention described below only are a part of embodiments of the invention, but not all embodiments. Based on the described embodiments of the invention, all other embodiments obtained by ordinary skill in the art without creative effort belong to the scope of protection of the invention.

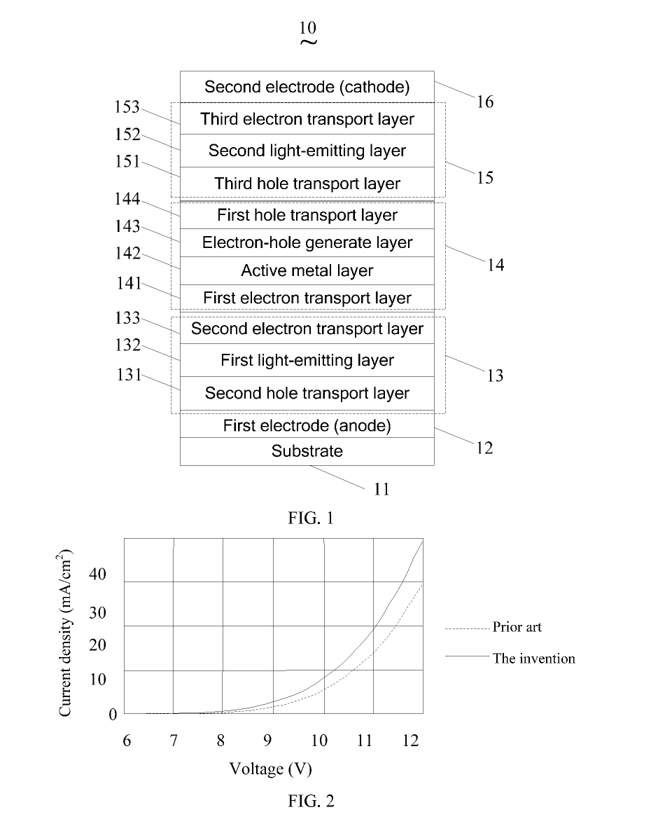

Referring to FIG. 1, FIG. 1 is a schematic structural view of a tandem-type organic light-emitting diode provided by an embodiment of the invention. As illustrated in FIG. 1, the tandem-type organic light-emitting diode 10 provided by the embodiment of the invention includes a substrate 11, a first electrode 12, a first light-emitting unit 13, a charge generate layer 14, a second light-emitting unit 15 and a second electrode 16.

The first electrode 12 is disposed on the substrate 11. The first light-emitting unit 13 is disposed on the first electrode 12. The charge generate layer 14 is disposed on the first light-emitting unit 13. The second light-emitting unit 15 is disposed on the charge generate layer 14. The second electrode 16 is disposed on the second light-emitting unit 15. The charge generate layer 14 is configured (i.e., structured and arranged) for providing electrons or holes required by the first light-emitting unit 13 and the second light-emitting unit 15 for light-emitting, so that the first light-emitting unit 13 can emit light under the effect of the charge generate layer 14 and the first electrode 12, and the second light-emitting unit 15 can emit light under the effect of the charge generate layer 14 and the second electrode 16. That is, the charge generate layer 14 makes the first light-emitting unit 13 and the second light-emitting unit 15 be connected in series between the first electrode 12 and the second electrode 16, so that a tandem-type organic light-emitting diode is achieved and the light-emitting efficiency can be increased.

In this embodiment, the charge generate layer 14 includes stacked first electrode transport layer 141 and active metal layer 142. That is, the first electron transport layer 141 and the active metal layer 142 are disposed together in the form of individual layers. So that, in a manufacturing process, the first electron transport layer 141 and the active metal layer 142 can be formed independently, the formations thereof are not mutually influenced, and the difficulty of the manufacturing process is reduced. Furthermore, since the active metal layer 142 is formed independent from the formation of the first electron transport layer 141, during the manufacturing process, as long as control the thickness of the active metal layer 142, the tandem-type organic light-emitting diode 10 with stable performance can be achieve and further is in favor of mass production.

In this embodiment, the charge generate layer 14 further includes an electron-hole generate layer 143 and a first hoe transport layer 144 sequentially stacked on the first electron transport layer 141 and the active metal layer 142. The first light-emitting unit 13 includes a second hole transport layer 131, a first light-emitting layer 132 and a second electron transport layer 133 sequentially stacked in that order. The second light-emitting unit 15 includes a third hole transport layer 151, a second light-emitting layer 152 and a third electron transport layer 153 sequentially stacked in that order.

In this embodiment, the first electrode 12 and the second electrode 16 respectively are an anode and a cathode. Accordingly, the second hole transport layer 131, the first light-emitting layer 132 and the second electron transport layer 133 of the first light-emitting unit 13 are sequentially stacked on the anode in that order. The first electron transport layer 141, the active metal layer 142, the electron-hole generate layer 143 and the first hole transport layer 144 of the charge generate layer 14 are sequentially stacked on the first light-emitting unit 13 in that order, i.e., sequentially stacked on the second electron transport layer 133. The third hole transport layer 151, the second light-emitting layer 152 and the third electron transport layer 153 of the second light-emitting unit 15 are sequentially stacked on the charge generate layer 14 in that order, i.e., sequentially stacked on the first hole transport layer 144.

The first electron transport layer 141, the second electron transport layer 133 and the third electron transport layer 153 can be made of Bphen (4,7-diphenyl-1,10-phenanthroline) and are used for transporting electrons.

A thickness of the active metal layer 142 is in the range of 0.5 nm-5 nm, and in this embodiment preferably is 1 nm. The active metal layer 142 preferably is made of an active metal with a work function less than 3 eV, for example the active metal layer 142 is made of one of Li (lithium), Na (sodium), K (potassium), Ru (ruthenium), Cs (cesium), Ca (calcium), Sr (strontium), Ba (barium), Ce (cerium), Pr (praseodymium), Sm (samarium), Eu (europium), Tb (terbium), Yb (ytterbium), or any combination thereof The active metal layer 142 also can be made of other reaction active metal instead.

The electron-hole generate layer 143 includes a HATCN (hexanitrilehexaazatriphenylene) layer or a metal oxide layer. The metal oxide layer is formed by one of MoO3 (molybdenum oxide), WO3 (tungsten trioxide), V2O5 (vanadium pentoxide) and ReO3 (rhenium oxide), or any combination thereof.

The first hole transport layer 144, the second hole transport layer 131 and the third hole transport layer 151 can be made of NPB (N, N′-diphenyl-N, N′-(1-naphthyl)-1,1′-biphenyl-4,4′-diamine) and are used for transporting holes.

In this embodiment, light emitted from the tandem-type organic light-emitting diode 10 is white. Accordingly, one of the first light-emitting unit 13 and the second light-emitting unit 15 is a blue light-emitting element, and the other one of the first light-emitting unit 13 and the second light-emitting unit 15 is a yellow light-emitting element; or the first light-emitting unit 13 and the second light-emitting unit 15 both are white light-emitting elements instead.

Concretely, the required light can be obtained by coating corresponding color phosphor materials or other color materials. That is, the first light-emitting layer 132 of the first light-emitting unit 13 and the second light-emitting layer 152 of the second light-emitting unit 15 may be coated with corresponding color phosphor materials or other color materials. For example, when the first light-emitting unit 13 is a blue light-emitting element and the second light-emitting unit 15 is a yellow light-emitting element, the first light-emitting layer 132 may be coated with a blue phosphor, and the second light-emitting layer may be coated with a yellow phosphor.

In this embodiment, the first electron transport layer 141 and the active metal layer 142 are formed in the form of individual layers by evaporation. Of course, the electron-hole generate layer 143, the first hole transport layer 144, the second hole transport layer 131, the first light-emitting layer 132, the second electron transport layer 133, the third hole transport layer 151, the second light-emitting layer 152 and the third electron transport layer 153 also can be formed in the form of individual layers by evaporation.

A working principle of the tandem-type organic light-emitting diode 10 in this embodiment will be described below.

It can be seen from the foregoing, the charge generate layer 14 is configured for providing electrons or holes required by the first light-emitting unit 13 and the second light-emitting unit 15 for light-emitting. Since the first electrode 12 is the anode and the second electrode 16 is the cathode in this embodiment, the charge generate layer 14 concretely provides the first light-emitting unit 13 with electrons and provides the second light-emitting unit 15 with holes.

Concretely speaking, when the electron-hole generate layer 143 being the HATCN layer is taken as an example, the HATCN layer has a very low LUMO (Lowest Unoccupied Molecular Orbital), an electron can transition from the HOMO (Highest Occupied Molecular Orbital) of the first hole transport layer 144 to the LUMO of the HATCN layer to thereby form dipoles. After a forward voltage is applied, the dipoles are separated into a hole and an electron under the effect of an external electric field. The electron needs to overcome energy barrier from the HATCN layer to the first electron transport layer 141, and the active metal layer 142 in this embodiment is configured just for overcoming the energy barrier. That is, on the assist of the active metal layer 142, the electron overcomes the energy barrier from the HATCN layer to the first electron transport layer and then is transported to the first electron transport layer 141, the first electron transport layer 141 transports the electron to the second electron transport layer 133 of the first light-emitting unit 13, the second electron transport layer 133 further transports the electron to the first light-emitting layer 132, the second hole transport layer 131 transports a hole provided from the anode to the first light-emitting layer 132, and thereby the electron and the hole are recombined in the first light-emitting layer 132 to emit light.

In addition, the hole formed in the HATCN layer is transported to the third hole transport layer 151 of the second light-emitting unit 15 through the first hole transport layer 144, the third hole transport layer 151 further transports the hole to the second light-emitting layer 152, the third electron transport layer 153 transports an electron provided from the cathode to the second light-emitting layer 152, so that the electron and the hole are recombined in the second light-emitting layer 152 to emit light. Accordingly, the light-emitting process of the tandem-type organic light-emitting diode 10 is completed.

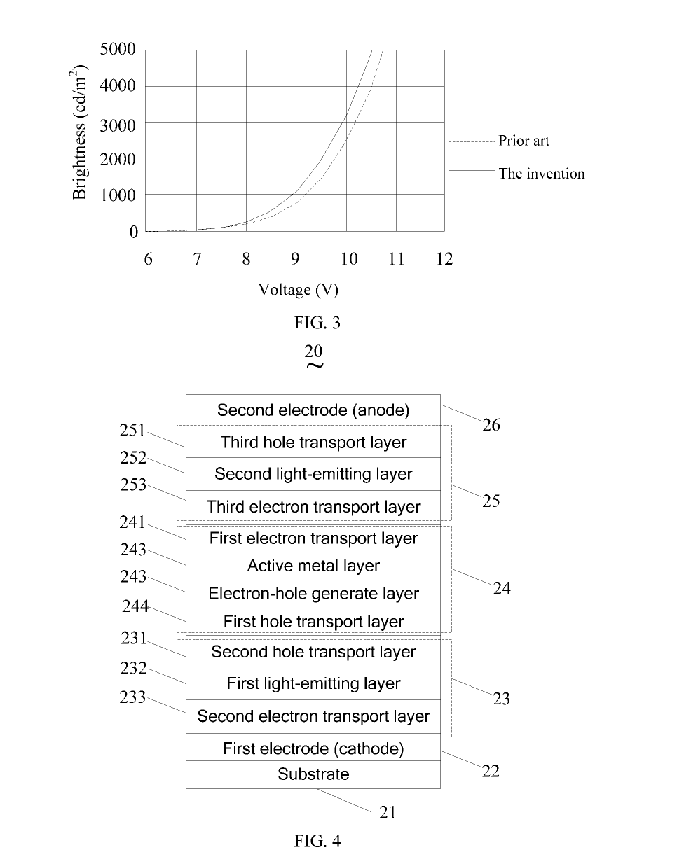

Referring to FIGS. 2 and 3, FIG. 2 is a voltage-current density diagram of tandem-type OLEDs of the invention and the prior art, and FIG. 3 is a voltage-brightness diagram of tandem-type OLEDs of the invention and the prior art.

As seen from FIG. 2, at a same voltage, a current density of the tandem-type organic light-emitting diode of the invention is greater than that of the tandem-type organic light-emitting diode in the prior art. As seen from FIG. 3, at a same voltage, a brightness of the tandem-type organic light-emitting diode of the invention is higher than that of the tandem-type organic light-emitting diode in the prior art. Accordingly, by the disposition of the first electron transport layer 141 and the active metal layer 142 in the form of individual layers in the embodiment of invention, the light-emitting efficiency of the tandem-type organic light-emitting diode 10 is significantly improved.

Referring to FIG. 4, FIG. 4 is a schematic structural view of another tandem-type organic light-emitting diode provided by an embodiment of the invention. As illustrated in FIG. 4, the organic light-emitting diode 20 includes a substrate 21, a first electrode 22, a first light-emitting unit 23, a charge generate layer 24, a second light-emitting unit 25 and a second electrode 26.

In this embodiment, a difference of the tandem-type organic light-emitting diode 20 from the foregoing tandem-type organic light-emitting diode 10 is that: the first electrode 21 and the second electrode 26 of the tandem-type organic light-emitting diode 20 respectively are a cathode and an anode.

Correspondingly, detailed structural arrangements of the first light-emitting layer 23, the charge generate layer 24 and the second light-emitting unit 25 are reversed to the foregoing. Concretely speaking, a second electron transport layer 233, a first light-emitting layer 232 and a second hole transport layer 231 of the first light-emitting unit 23 are sequentially stacked on the cathode in that order. A first hole transport layer 244, an electron-hole generate layer 243, an active metal layer 242 and a first electron transport layer 241 are sequentially stacked on the first light-emitting unit 23, i.e., sequentially stacked on the second hole transport layer 231. A third electron transport layer 253, a second light-emitting layer 252 and a third hole transport layer 251 are sequentially stacked on the charge generate layer 24, i.e., sequentially stacked on the first electron transport layer 241.

A working principle of the tandem-type organic light-emitting diode 20 in this embodiment is the same as that of the foregoing tandem-type organic light-emitting diode 10, and thus will be repeated herein.

In another embodiment, the invention further provides a tandem-type organic light-emitting diode. The tandem-type organic light-emitting diode includes a charge generate layer, and the charge generate layer includes a first electron transport layer and an active metal layer stacked with each other.

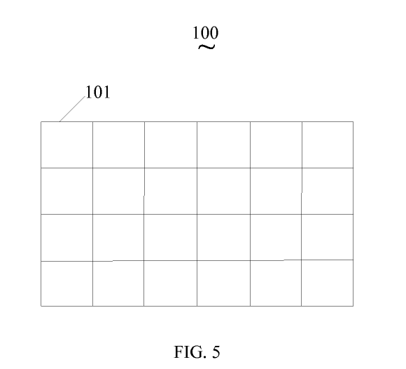

In still another embodiment, the invention still further provides a display device. As shown in FIG. 5, the display device 100 in this embodiment includes multiple (i.e., more than one) pixel units 101 arranged in an array. Each pixel unit 101 is the foregoing tandem-type organic light-emitting diode 10 or 20.

In summary, the tandem-type organic light-emitting diode of the invention disposes a charge generate layer including a first electron transport layer and an active metal layer, the first electron transport layer and the active metal layer may be formed independently, the manufacturing processes as well as working processes thereof are not mutually influenced, and therefore the tandem-type organic light-emitting diode with stable performance is obtained and further in favor of mass production.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

1. A tandem-type organic light-emitting diode comprising:
a substrate;
a first electrode, disposed on the substrate;
a first light-emitting unit, disposed on the first electrode;
a charge generating layer, disposed on the first light-emitting unit;
a second light-emitting unit, disposed on the charge generating layer and thereby the charge generating layer is arranged between the first light-emitting unit and the second light-emitting unit;
a second electrode, disposed on the second light-emitting unit;
wherein the charge generating layer comprises a first hole transport layer, an electron-hole pair generating layer, an active metal layer and a first electron transport layer sequentially stacked in that order, the active metal layer and the first electron transport layer are disposed in the form of individual layers;
wherein the first light-emitting unit a second hole transport layer, a first light-emitting layer and a second electron transport layer sequentially stacked in that order;
wherein the second light-emitting unit comprises a third hole transport layer, a second light-emitting layer and a third electron transport layer sequentially stacked in that order.

2. (canceled)

3. The tandem-type organic light-emitting diode as claimed in claim 1, wherein the active metal layer has a thickness in the range of 0.5 nm-5 nm.

4. The tandem-type organic light-emitting diode as claimed in claim 1, wherein the active metal layer is made of an active metal with a work function less than 3 eV.

5. The tandem-type organic light-emitting diode as claimed in claim 1, wherein the active metal layer is made of one of lithium (Li), sodium (Na), potassium (K), ruthenium (Ru), cesium (Cs), calcium (Ca), strontium (Sr), barium (Ba), cerium (Ce), praseodymium (Pr), samarium (Sm), europium (Eu), terbium (Tb) and ytterbium (Yb), or a combination thereof.

6. The tandem-type organic light-emitting diode as claimed in claim 1, wherein the electron-hole pair generating layer comprises a hexanitrilehexaazatriphenylene (HATCN) layer or a metal oxide layer; the metal oxide layer is made of one of molybdenum oxide, tungsten trioxide, vanadium pentoxide and rhenium oxide, or a combination thereof.

7. (canceled)

8. The tandem-type organic light-emitting diode as claimed in claim 1, wherein one of the first light-emitting unit and the second light-emitting unit is a blue light-emitting element, and the other one of the first light-emitting unit and the second light-emitting unit is a yellow light-emitting element; or the first light-emitting unit and the second light-emitting unit both are white light-emitting elements.

9. A tandem-type organic light-emitting diode comprising a charge generating layer, wherein the charge generating layer comprises a hole transport layer, an electron-hole pair generating layer, an active metal layer and an electron transport layer sequentially stacked in that order, the active metal layer and the electron transport layer are disposed in the form of individual layers by evaporation.

10. A display device comprising a plurality of pixel units arranged in an array, each of the plurality of pixel units being a tandem-type organic light-emitting diode; the tandem-type organic light-emitting diode comprising:
a substrate;
a first electrode, disposed on the substrate;
a first light-emitting unit, disposed on the first electrode;
a charge generating layer, disposed on the first light-emitting unit;
a second light-emitting unit, disposed on the charge generating layer and thereby the charge generating layer is arranged between the first light-emitting unit and the second light-emitting unit;
a second electrode, disposed on the second light-emitting unit;
wherein the charge generating layer comprises a first hole transport layer, an electron-hole pair generating layer, an active metal layer and a first electron transport layer sequentially stacked in that order, the active metal layer and the first electron transport layer are disposed in the form of individual layers;
wherein the first light-emitting unit a second hole transport layer, a first light-emitting layer and a second electron transport layer sequentially stacked in that order;
wherein the second light-emitting unit comprises a third hole transport layer, a second light-emitting layer and a third electron transport layer sequentially stacked in that order.

11. (canceled)

12. The display device as claimed in claim 10, wherein the active metal layer has a thickness in the range of 0.5 nm-5 nm.

13. The display device as claimed in claim 10, wherein the active metal layer is made of an active metal with a work function less than 3 eV.

14. The display device as claimed in claim 10, wherein the active metal layer is made of one of lithium (Li), sodium (Na), potassium (K), ruthenium (Ru), cesium (Cs), calcium (Ca), strontium (Sr), barium (Ba), cerium (Ce), praseodymium (Pr), samarium (Sm), europium (Eu), terbium (Tb) and ytterbium (Yb), or a combination thereof.

15. The display device as claimed in claim 10, wherein the electron-hole generate layer comprises a hexanitrilehexaazatriphenylene (HATCN) layer or a metal oxide layer; the metal oxide layer is made of one of molybdenum oxide, tungsten trioxide, vanadium pentoxide and rhenium oxide, or a combination thereof.

16. (canceled)

17. The display device as claimed in claim 10, wherein one of the first light-emitting unit and the second light-emitting unit is a blue light-emitting element, and the other one of the first light-emitting unit and the second light-emitting unit is a yellow light-emitting element; or the first light-emitting unit and the second light-emitting unit both are white light-emitting elements.

18. The tandem-type organic light-emitting diode as claimed in claim 1, wherein when the first electrode acts as an anode and the second electrode acts as a cathode, the first electron transport layer is disposed adjacent to the second electrode transport layer of the first light-emitting unit and the first hole transport layer is disposed adjacent to the third hole transport layer of the second light-emitting unit; whereas, when the second electrode acts as an anode and the first electrode acts as a cathode, the first electron transport layer is disposed adjacent to the third electron transport layer of the second light-emitting unit and the first hole transport layer is disposed adjacent to the second hole transport layer of the first light-emitting unit.

19. The display device as claimed in claim 10, wherein when the first electrode acts as an anode and the second electrode acts as a cathode, the first electron transport layer is disposed adjacent to the second electrode transport layer of the first light-emitting unit and the first hole transport layer is disposed adjacent to the third hole transport layer of the second light-emitting unit; whereas, when the second electrode acts as an anode and the first electrode acts as a cathode, the first electron transport layer is disposed adjacent to the third electron transport layer of the second light-emitting unit and the first hole transport layer is disposed adjacent to the second hole transport layer of the first light-emitting unit.
